(19) United States
(12) Patent Application Publication
(10) Pub. No.: US 2011/0214725 A1
(43) Pub. Date: Sep. 8, 2011

(54) PHOTOVOLTAIC DEVICE WITH GRADED BUFFER LAYER

(75) Inventor: Markus E. Beck, Scotts Valley, CA (US)

(73) Assignee: First Solar, Inc., Perrysburg, OH (US)

(21) Appl. No.: 13/035,584

(22) Filed: Feb. 25, 2011

Related U.S. Application Data
(60) Provisional application No. 61/310,757, filed on Mar. 5, 2010.

(51) Int. Cl. H01L 31/065; H01L 31/18

(52) U.S. Cl. 136/255; 438/94; 438/85; 257/E31.005

(57) ABSTRACT

A photovoltaic device can include a graded bandgap buffer layer.

### CLAIM OF PRIORITY

This application claims priority to U.S. Provisional Patent Application No. 61/310,757, filed on Mar. 5, 2010, which is incorporated by reference in its entirety.

### TECHNICAL FIELD

This invention relates to manufacturing a photovoltaic device.

### BACKGROUND

Manufacturing a photovoltaic device can include forming multiple layers adjacent to a substrate. For example, a photovoltaic device can include a conducting layer formed adjacent to the substrate, a semiconductor absorber layer adjacent to the conducting layer, and a buffer layer adjacent to the semiconductor absorber layer. A semiconductor window layer can be formed adjacent to the buffer layer and a transparent conductive oxide layer can be formed adjacent to the semiconductor window layer.

### DESCRIPTION OF DRAWINGS

FIG. 1 is a schematic of a photovoltaic device.

FIG. 2 is a schematic depicting the precursor gas pulse sequence of a manufacturing process.

FIG. 3 is a schematic depicting the precursor gas pulse sequence of a manufacturing process.

FIG. 4 is a schematic depicting the precursor gas pulse sequence of a manufacturing process.

FIG. 5 is a schematic depicting the precursor gas pulse sequence of a manufacturing process.

FIG. 6 is a schematic depicting the precursor gas pulse sequence of a manufacturing process.

FIG. 7 is a schematic depicting the precursor gas pulse sequence of a manufacturing process.

FIG. 8 is a schematic depicting the precursor gas pulse sequence of a manufacturing process.

FIG. 9 is a schematic depicting the precursor gas pulse sequence of a manufacturing process.

FIG. 10 is a schematic of a photovoltaic device.

FIG. 11 is a schematic of a photovoltaic device buffer layer.

FIG. 12 is a schematic of a photovoltaic device buffer layer metal chalcogenide layer.

### DETAILED DESCRIPTION

Photovoltaic devices can include multiple layers formed on a substrate (or superstrate). For example, a photovoltaic device can include a conducting layer, a semiconductor absorber layer, a buffer layer, a semiconductor window layer, and a transparent conductive oxide (TCO) layer, formed in a stack on a substrate. Each layer may in turn include more than one layer or film. For example, the semiconductor window layer and semiconductor absorber layer together can be considered a semiconductor layer. The semiconductor layer can include a first film created (for example, formed or deposited) on the TCO layer and a second film created on the first film. Additionally, each layer can cover all or a portion of the device and/or all or a portion of the layer or substrate underlying the layer. For example, a “layer” can mean any amount of any material that contacts all or a portion of a surface.

Manufacturing a photovoltaic device including a copper-indium-gallium-selenium (CIGS) can include forming a buffer layer. The buffer layer is a layer formed between the CIGS absorber layer and other window layers. The buffer layer can be formed adjacent to the CIGS semiconductor absorber layer and between the semiconductor absorber layer and the other window layers. The buffer layer can be used to create a suitable band gap between the semiconductor absorber layer and semiconductor window layer. The buffer layer can also buffer defects and imperfections at the absorber interface, which can help minimize interface recombination. Some available deposition techniques (e.g. sputtering, evaporation) have difficulties in achieving atomic level thickness or composition control of deposited film, which can be desirable in a CIGS photovoltaic device buffer layer. A new deposition process is developed to address this problem.

Advantageously, atomic layer deposition (ALD) can form a graded bandgap film by providing monolayer resolution of film growth and composition. In some embodiments, ALD can be used to form a buffer layer of a CIGS photovoltaic device. The buffer layer of a CIGS photovoltaic device can include one or more layers (for example, one or more monolayers) of a metal chalcogenide. The buffer layer can include metals such as indium and zinc. The buffer layer can include chalcogenides such as zinc oxide, zinc sulfide or zinc selenide, or combinations thereof in combination with indium oxide, indium sulfide or indium selenide, or combinations thereof. Typical buffer layer thicknesses on CIGS absorbers for indium sulfide (In₂S₃) can be in the range of 10-50 nm deposited at approximately 180-220° C. Typical buffer layer thicknesses on CIGS absorbers for buffers including a combination of zinc oxide and zinc sulfide are approximately 25 to 30 nm can be deposited in the range of 110 to 150° C.

In some CIGS photovoltaic devices, the device was made with a cadmium sulfide (CdS) buffer layer. Replacing CdS (bandgap of 2.42 eV) with zinc or indium chalcogenides can improve current collection in the blue region of the spectrum due to the resulting higher bandgap of the respective materials. Additionally, a better control of buffer layer thickness, structure, and composition is also desired to minimize interface recombination.

ALD is a method of applying thin films to various substrates with atomic scale precision. Similar in chemistry to chemical vapor deposition (CVD), except that the ALD reaction breaks the CVD reaction into two half-reactions, keeping the precursor materials separate during the reaction. Additionally, ALD film growth is self-limited and based on surface reactions, which makes achieving atomic scale deposition control possible. By keeping the precursors separate throughout the coating process, atomic layer thickness control of film grown can be obtained as fine as atomic/molecular scale per monolayer. ALD includes releasing sequential precursor gas pulses to deposit a film one layer at a time on the substrate. The precursor gas can be introduced into a process chamber and produces a precursor monolayer of material on the device surface. A second precursor of gas can be then introduced into the chamber reacting with the first precursor to produce a monolayer of film on the substrate/absorber surface. The precursor monolayers (for example, a metal precursor monolayer or chalcogen precursor monolayer) can have a thickness of less than about two molecules, for example, about one molecule. After the precursors react, the resulting metal chalcogenide layer can also have a thickness of less than about two molecules, for example, about one molecule. A monolayer, for example, a precursor monolayer or a metal chalcogenide monolayer can be continuous or discontinuous and can contact all or a portion of a surface. For example, a monolayer can contact more that about 80%, more than about 85%, more than about 90%, more than about 95%, more than about 98%, more than about 99%, more than about 99.9%, or about 100% of a surface. ALD has two fundamental mechanisms: chemisorption saturation process and sequential surface chemical reaction process.

A buffer layer formed using an ALD process can be graded, for example, by forming multiple buffer monolayers adjacent to the semiconductor absorber layer, with each buffer monolayer including a material having a different bandgap from immediately adjacent buffer monolayers. For example, a graded buffer layer can include a first buffer monolayer immediately adjacent to the semiconductor window layer including a first buffer material such as indium sulfide and having a first bandgap. A second buffer monolayer can be formed immediately adjacent to the first buffer monolayer and can include a second buffer material, such as zinc sulfide, which has a different (greater) bandgap than the first buffer material. By providing multiple buffer monolayers including different materials and having successively increasing or decreasing bandgaps, the buffer layer can be graded.

A method of manufacturing a photovoltaic device can include forming a semiconductor absorber layer adjacent to a substrate. The semiconductor absorber layer can include copper, indium, gallium, selenium and/or sulfur. The method can include forming a buffer layer adjacent to the semiconductor absorber layer. Forming the buffer layer can include forming a first metal chalcogenide layer having a first bandgap adjacent to the semiconductor absorber layer and forming a second metal chalcogenide layer having a second bandgap adjacent to the first metal chalcogenide layer. Forming the first metal chalcogenide layer can include pulsing a first metal precursor and pulsing a first chalcogen precursor. Forming the second metal chalcogenide layer can include pulsing a second metal precursor and pulsing a second chalcogen precursor.

Forming the first metal chalcogenide layer can include forming one or more first metal chalcogenide monolayers. Forming the second metal chalcogenide layer can include forming one or more second metal chalcogenide monolayers. Each of the first metal chalcogenide monolayers can include a same first metal chalcogenide. Each of the second metal chalcogenide monolayers can include a same second metal chalcogenide.

The method can include forming a conducting layer adjacent to the substrate before forming the semiconductor absorber layer adjacent to the substrate. The method can include forming a transparent conductive oxide layer adjacent to the buffer layer. The method can include forming a semiconductor window layer adjacent to the buffer layer before forming a transparent conductive oxide layer adjacent to the buffer layer.

Each of the first and second metal precursors can include indium or zinc. Each of the first and second metal precursors can include trimethylindium, indium acetylacetonate, indium chloride, dimethylzinc or trimethylzinc. Each of the first and second chalcogen precursors can include oxygen, sulfur, or selenium. Each of the first and second chalcogen precursors can include water, ozone, sulfur dioxide, hydrogen sulfide, hydrogen selenide, or diethylselenide. Each of the first and second metal chalcogenide layers can include indium sulfide, indium selenide, indium oxide, zinc sulfide, zinc selenide, or zinc oxide.

The method can include forming a third metal chalcogenide layer adjacent to the first metal chalcogenide layer before forming the second metal chalcogenide layer. The third metal chalcogenide layer can have a bandgap between the first bandgap and the second bandgap. Forming the third metal chalcogenide layer can include pulsing a third metal precursor and pulsing a third chalcogen precursor. The third metal chalcogenide layer can include indium sulfide, indium selenide, indium oxide, zinc sulfide, zinc selenide, or zinc oxide. The method can include forming a fourth metal chalcogenide layer adjacent to the third metal chalcogenide layer before forming the second metal chalcogenide layer. The fourth metal chalcogenide layer can have a bandgap between the third bandgap and the second bandgap. The fourth metal chalcogenide layer can include indium sulfide, indium selenide, indium oxide, zinc sulfide, zinc selenide, or zinc oxide.

The method can include forming a fifth metal chalcogenide layer adjacent to the fourth metal chalcogenide layer before forming the second metal chalcogenide layer. The fifth metal chalcogenide layer can have a bandgap between the fourth bandgap and the second bandgap. The fifth metal chalcogenide layer can include indium sulfide, indium selenide, indium oxide, zinc sulfide, zinc selenide, or zinc oxide.

The method can include forming a sixth metal chalcogenide layer adjacent to the fifth metal chalcogenide layer before forming the second metal chalcogenide layer. The sixth metal chalcogenide can have has a bandgap between the fifth bandgap and the second bandgap. The sixth metal chalcogenide layer can include indium sulfide, indium selenide, indium oxide, zinc sulfide, zinc selenide, or zinc oxide.

The method can include forming at least one additional metal chalcogenide layer adjacent to the sixth metal chalcogenide layer before forming the second metal chalcogenide layer. The at least one additional metal chalcogenide layer can have a bandgap between the sixth bandgap and the second bandgap. At least one additional metal chalcogenide layer can include indium sulfide, indium selenide, indium oxide, zinc sulfide, zinc selenide, or zinc oxide.

The method can include displacing one of the precursors with inert gas after pulsing the precursor. The method can include heating the substrate before pulsing a precursor. The method can include controlling the temperature based on the metal chalcogenide layer being formed.

A structure can include a substrate, a conducting layer adjacent to the substrate, and a semiconductor absorber layer adjacent to the conducting layer. The semiconductor absorber layer can include copper, indium, gallium, selenium and/or sulfur. The structure can include a buffer layer adjacent to the semiconductor absorber layer. The buffer layer can include a first metal chalcogenide layer adjacent to the semiconductor absorber layer and having a first bandgap and a second metal chalcogenide layer adjacent to the first metal chalcogenide layer and having a second bandgap.

The structure can include a semiconductor window layer adjacent to the buffer layer. The structure can include a transparent conductive oxide layer adjacent to the semiconductor window layer. Each of the first and second metal chalcogenide layers can include a material selected from the group consisting of indium sulfide, indium selenide, indium oxide, zinc sulfide, zinc selenide, and zinc oxide. Each of the first and second metal chalcogenide layers can include one or more metal chalcogenide monolayers formed by pulsing a metal precursor and pulsing a chalcogen precursor.

The structure can include a third metal chalcogenide layer between the first metal chalcogenide layer and the second metal chalcogenide layer. The third metal chalcogenide layer can have a bandgap between the first bandgap and the second bandgap. The third metal chalcogenide layer can include indium sulfide, indium selenide, indium oxide, zinc sulfide, zinc selenide, or zinc oxide.

The structure can include a fourth metal chalcogenide layer between the third metal chalcogenide layer and the second metal chalcogenide layer. The fourth metal chalcogenide layer can have a bandgap between the third bandgap and the second bandgap. The fourth metal chalcogenide layer can include indium sulfide, indium selenide, indium oxide, zinc sulfide, zinc selenide, or zinc oxide.

The structure can include a fifth metal chalcogenide layer between the fourth metal chalcogenide layer and the second metal chalcogenide layer. The fifth metal chalcogenide layer can have a bandgap between the fourth bandgap and the second bandgap. The fifth metal chalcogenide layer can include indium sulfide, indium selenide, indium oxide, zinc sulfide, zinc selenide, or zinc oxide.

The structure can include a sixth metal chalcogenide layer between the fifth metal chalcogenide layer and the second metal chalcogenide layer. The sixth metal chalcogenide layer can have a bandgap between the fifth bandgap and the second bandgap. The sixth metal chalcogenide layer can include indium sulfide, indium selenide, indium oxide, zinc sulfide, zinc selenide, or zinc oxide.

The first metal chalcogenide layer can include indium and the second metal chalcogenide layer can include zinc. The first metal chalcogenide layer can include zinc and the second metal chalcogenide layer can include indium. The buffer layer can include a plurality of metal chalcogenide layers between the first metal chalcogenide layer and the second metal chalcogenide layer.

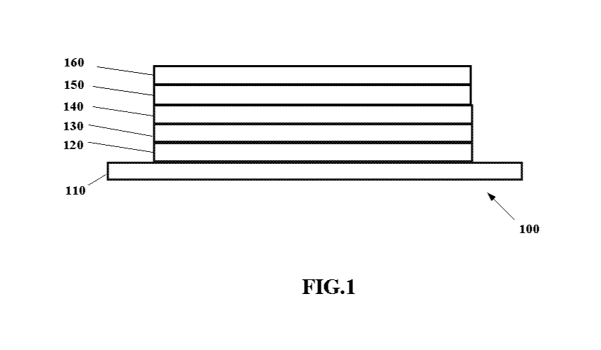

Referring to FIG. 1, CIGS photovoltaic module 100 can include conducting layer 120, semiconductor absorber layer 130, buffer layer 140, semiconductor window layer 150, and transparent conductive oxide (TCO) layer 160 formed in a stack on substrate 110. Each layer may in turn include more than one layer or film. Photovoltaic module 100 can be formed by forming one or more layers by any suitable method. Conducting layer 120 can be formed on substrate 110. Conducting layer 120 can include any suitable material. For example, conducting layer 120 can include a metal. Semiconductor absorber layer 130 can be formed adjacent to conductor layer 120. Semiconductor absorber layer 130 can be formed by any suitable method and can include copper, indium, gallium, selenium, and/or sulfur.

Next, buffer layer 140 can be formed adjacent to semiconductor absorber layer 130. Buffer layer 140 can be formed using ALD. For example, buffer layer 140 can be formed by directing a first metal precursor toward substrate 110, ceasing to direct the first metal precursor toward substrate 110, then directing a first chalcogen precursor toward substrate 110. The first metal precursor and first chalcogen precursor can react to form a first metal chalcogenide layer. The first metal chalcogenide layer can include one or more metal chalcogenide monolayers, each formed by an ALD cycle including pulsing a metal precursor then pulsing a chalcogen precursor. A resulting metal chalcogenide monolayer can be about one molecule thick. Successive metal chalcogenide layers including the same or different metal chalcogenides can be formed to build buffer layer 140.

ALD can be used to deposit a buffer layer of a CIGS photovoltaic device including a metal chalcogenide, such as indium sulfide (e.g., In₂S₃), indium oxide (e.g., In₂O₃), or indium selenide (e.g., In₂Se₃) (or combinations thereof), zinc sulfide (e.g., ZnS), zinc oxide (e.g., ZnO), or zinc selenide (ZnS) (or combinations thereof). A buffer layer formed by ALD can include combinations of indium chalcogenides and zinc chalcogenides. A wide range of precursors can be used to provide a source for the metal and chalcogen. Typical organometallic (MO) precursors for zinc are dimethylzinc (DMZ, Zn(CH₃)₂) or diethylzinc (DEZ, Zn(C₂H₅)₂). Indium-based precursors can include trimethylindium (TMI, In(CH₃)₃), indium acetylacetonate (In(acac)₃), or indium chloride (InCl₃). Common sulfur sources are sulfur dioxide (SO₂) or hydrogen sulfide (H₂S), while oxygen is supplied as water (H₂O) or ozone (O₃). Selenium can be presented in the form of hydrogen selenide (H₂Se) or diethylselenide (DES, (C₂H₅)₂Se₂).

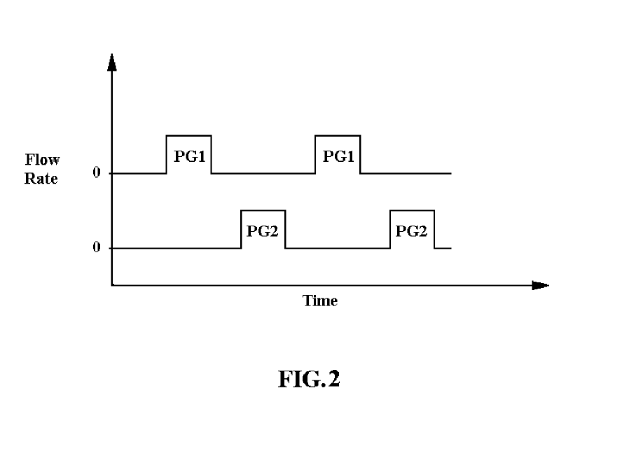

Referring to FIG. 2, a first metal precursor gas can be provided adjacent to the processing surface within the atomic layer deposition chamber effective to form a first monolayer on the substrate, which is designated by a precursor gas flow PG1. After forming the first monolayer of intermediate composition on the substrate, a first chalcogen precursor gas, different in composition from the first metal precursor gas, can be provided adjacent to the processing surface within the deposition chamber effective to react with the first monolayer and form a monolayer comprising the desired deposited composition. The first chalcogen precursor gas flow is designated by PG2. Each gas flow can be delivered as a pulse, in which the precursor gas is directed toward the substrate and then ceases being directed toward the substrate. The particular lengths and rates of the respective flowing, and the times there-between, can also be optimized to achieve the desired film thickness and composition. The cycle can be repeated with the same or different precursors to form the same or different metal chalcogenide monolayers. One or more of the same metal chalcogenide monolayers can form one metal chalcogenide layer.

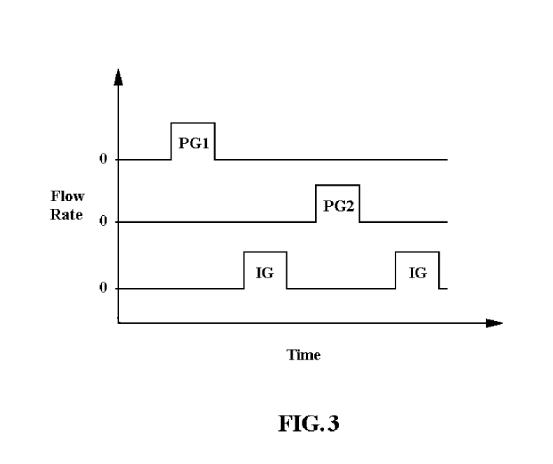

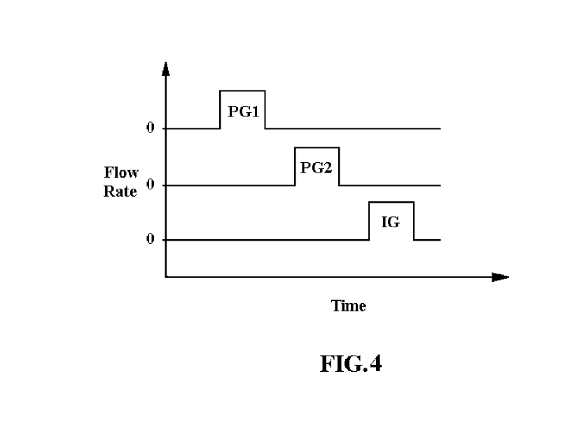

Referring to FIGS. 3 and 4, the process can include purging the chamber with an inert gas (IG) which is not reactive with of the metal or chalcogen precursor gas flows. The purge step can be performed between the metal and chalcogen precursor gas pulses (FIG. 3), after the precursor gas pulses and reaction (FIG. 4), or both.

Referring to FIG. 3, first metal precursor gas flow (PG1) can be introduced into the chamber, and adsorb and react with the surface. The dose of the metal precursor gas can be adjusted to obtain surface saturation, i.e. all available processing surface sites can be used for reaction with the precursor. When it is obtained, the precursor inlet can be closed and the chamber purged with inert gas (IG) leaving only the layer of reacted species on the processing surface. First chalcogen precursor is then introduced and react with the first layer forming a monolayer of the desired material (e.g. a metal chalcogenide for a buffer layer) while the byproducts desorb and are pumped out. The chamber can be purged again with inert gas (IG). This pulsing sequence corresponds to one ALD cycle. The sequence can be repeated up to a desired or predetermined number of cycles and the thickness can be controlled on a monolayer level.

The chalcogen ratio can be adjusted by controlling the pulse sequence and the precursor gases. For example, this can be done for the system including a zinc oxide and zinc sulfide combination (which can be represented as Zn(O,S)) where the O/S ratio has been tuned in a wide range resulting in different structures, optimal bandgaps, conductivity, and carrier concentration properties of the resulting films.

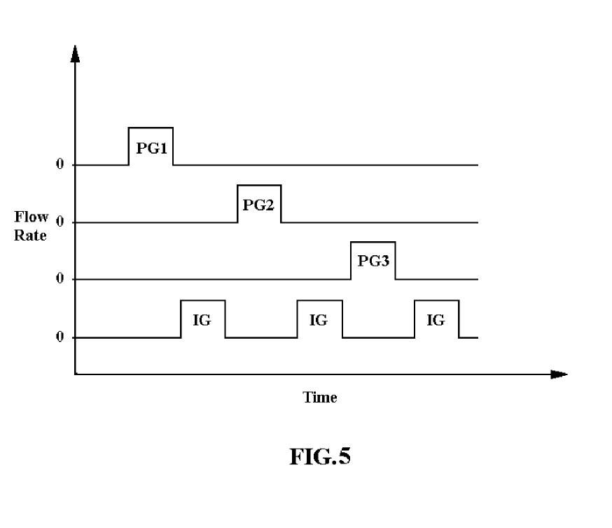

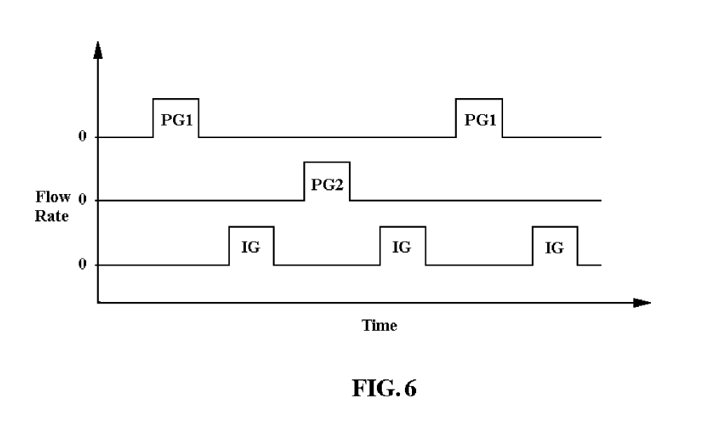

Referring to FIG. 5, an additional precursor gas flow PG3 which can be reactive with at least one of the first metal precursor and the first chalcogen precursor. Additional precursor gas flow PG3 can adjust the chalcogen ratio. Referring to FIG. 6, at least one of the first metal precursor and first chalcogen precursor can be reintroduced to adjust the ratio of material provided by the first and second precursors in the buffer layer. After an ALD cycle in which a first metal chalcogenide monolayer is formed from the first metal precursor and the first chalcogenide precursor, at least one additional ALD cycle is carried out to form a second metal chalcogenide monolayer adjacent to the first metal chalcogenide monolayer from the same or different metal and chalcogen precursors. Additional ALD cycles can be carried out to form additional metal chalcogenide monolayers which can be grouped to form two or more metal chalcogenide layers.

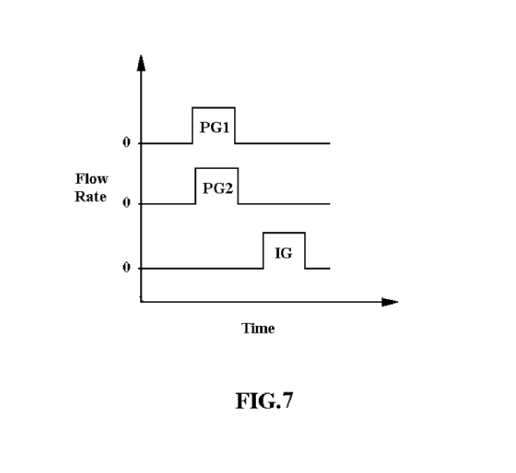

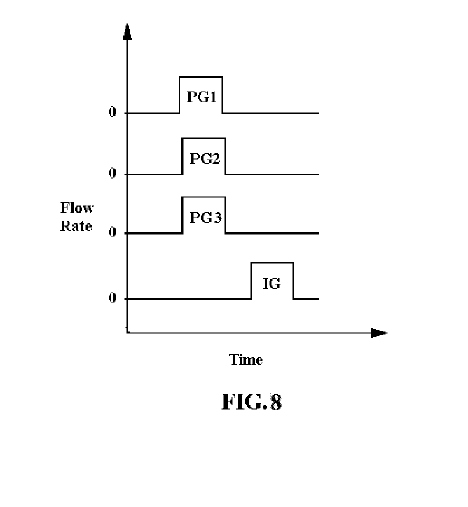

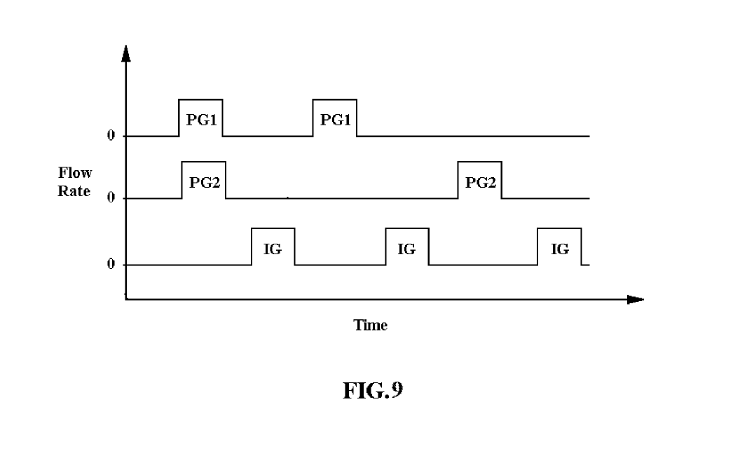

Referring to FIGS. 7 and 8, the introduction of precursors can take place at the same time or in an overlapping way. The film growth can be accelerated and at the same time particle generation increases due to gas phase reactions. Thereby, a higher deposition rate can be achieved. In this present invention, ALD, CVD, or their combination can be used as the deposition technique. Referring to FIG. 9, the deposition can include both CVD deposition cycle and ALD cycle to achieve better balance between the thickness control and deposition rate. Formation of the metal chalcogenide layers can occur at any suitable pressure and temperature and can include any suitable deposition technology, such as ALD and CVD (such as metalorganic CVD, plasma enhanced ALD/CVD).

Referring back to FIG. 1, after buffer layer 140 is formed, semiconductor window layer 150 can be formed adjacent to buffer layer 140. Semiconductor window layer 150 can be any suitable material and can be formed in any suitable manner. Transparent conductive oxide layer 160 can be formed adjacent to semiconductor window layer 150, from any suitable material, by any appropriate method.

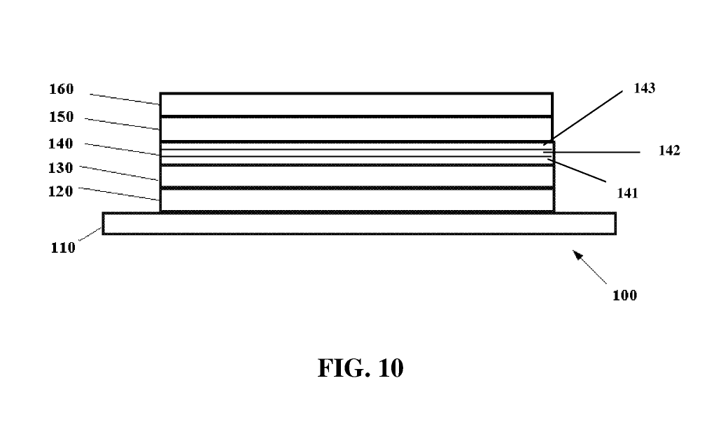

FIG. 10 shows photovoltaic device 100 including graded buffer layer 140. Graded buffer layer 140 can include any suitable number (for example, two or more) of metal chalcogenide layers 141, 142, 143, each of which can be formed by one or more ALD deposition cycles. First metal chalcogenide layer 141 can include any suitable material, such as indium or zinc. For example, first buffer monolayer 141 can include indium sulfide (e.g., In₂S₃), indium oxide (e.g., In₂O₃), or indium selenide (e.g., In₂Se₃) or any suitable indium chalcogenide (e.g., In₂(O,S,Se)₃), or zinc sulfide (e.g., ZnS), zinc oxide (e.g., ZnO), or zinc selenide (e.g., ZnSe) or any suitable zinc chalcogenide (e.g., Zn(O,S,Se)). First metal chalcogenide layer 141 can have a first bandgap. For example, if first metal chalcogenide layer 141 includes indium sulfide, the first bandgap can be about 2.0 eV to about 2.2 eV (e.g., about 2.1 eV).

Second metal chalcogenide layer 143 can include any suitable material, such as a indium or zinc. For example, second metal chalcogenide layer 143 can include indium sulfide (e.g., In₂S₃), indium oxide (e.g., In₂O₃), or indium selenide (e.g., In₂Se₃) or any suitable indium chalcogenide (e.g., In₂(O,S,Se)₃), or zinc sulfide (e.g., ZnS), zinc oxide (e.g., ZnO), or zinc selenide (e.g., ZnSe) or any suitable zinc chalcogenide (e.g., Zn(O,S,Se)). Second metal chalcogenide 143 can have a second bandgap, which can be higher than the first bandgap. For example, if second metal chalcogenide layer 143 includes zinc sulfide, the second bandgap can be about 3.6 eV to about 3.8 eV (e.g., about 3.7 eV).

Any suitable number and types of additional metal chalcogenide layers can be formed between first metal chalcogenide layer 141 and second metal chalcogenide layer 143. At least one additional metal chalcogenide layer 142 can include any suitable material. At least one additional metal chalcogenide layer 142 can include indium or zinc. At least one additional metal chalcogenide layer 142 can include, for example, indium sulfide (e.g., In₂S₃), indium oxide (e.g., In₂O₃), indium selenide (e.g., In₂Se₃) or any suitable indium chalcogenide (e.g., In₂(O,S,Se)₃), zinc sulfide (e.g., ZnS), zinc oxide (e.g., ZnO), zinc selenide (e.g., ZnSe) or any suitable zinc chalcogenide (e.g., Zn(O,S,Se)). At least one additional metal chalcogenide layer 142 can have an additional bandgap which can be between the first bandgap and the second bandgap. For example, if first metal chalcogenide layer 141 includes indium sulfide and has a bandgap of about 2.1 eV, and second metal chalcogenide layer 143 includes zinc sulfide and has a bandgap of about 3.7 eV, at least one additional metal chalcogenide layer 142 can include zinc oxide and can have an additional bandgap of about 3.1 to about 3.4 eV (e.g., about 3.25 eV). Graded buffer layer 140 thus can include multiple metal chalcogenide layers 141, 142, 143 with multiple graded bandgaps, to improve performance of photovoltaic device 100.

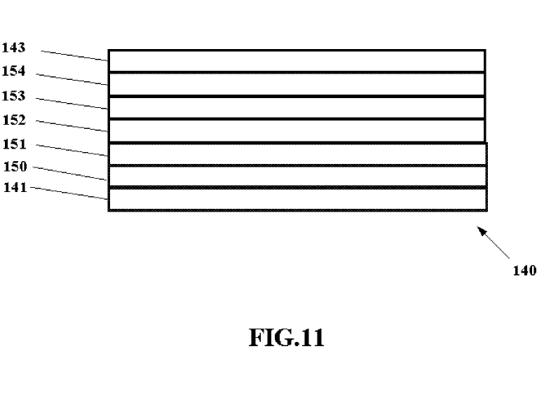

FIG. 11 depicts an enlarged view of buffer layer 140. Buffer layer 140 can include any suitable number of metal chalcogenide layers. Buffer layer 140 can include first metal chalcogenide layer 141 including a first metal chalcogenide and having a first bandgap and second metal chalcogenide layer 143 including a second metal chalcogenide and having a second bandgap. Buffer layer 140 can include additional metal chalcogenide layers formed between first metal chalcogenide layer 141 and second metal chalcogenide layer 143. The additional metal chalcogenide layers can be formed after first metal chalcogenide layer 141 and before second metal chalcogenide layer 143. For example, third metal chalcogenide layer 150 can be formed adjacent to first metal chalcogenide layer 141 (similar to at least one additional metal chalcogenide layer 142 in FIG. 10). Third metal chalcogenide layer 150 include a third metal chalcogenide having a bandgap different from the bandgaps of adjacent metal chalcogenide layers. As a result, buffer layer 140 can include a stack of any suitable number of metal chalcogenide layers. The metal chalcogenide layers can have different bandgaps. The bandgap profile can have a monotonic bandgap gradient, notched bandgap gradient, or any suitable bandgap profile. For a monotonic bandgap gradient buffer layer stack, the bandgap profile can be monotonic increase or decrease. For a notched bandgap gradient buffer layer stack, the bandgap of third metal chalcogenide layer 150 can be smaller than the bandgaps of both first metal chalcogenide layer 141 and second metal chalcogenide layer 143.

Fourth metal chalcogenide layer 151 can be formed adjacent to third metal chalcogenide layer 150; fifth metal chalcogenide layer 152 can be formed adjacent to fourth metal chalcogenide layer 151; sixth metal chalcogenide layer 153 can be formed adjacent to fifth metal chalcogenide layer 152; and one or more additional chalcogenide metal layers 154 can be formed adjacent to sixth metal chalcogenide layer 153. Each metal chalcogenide layer can include any suitable material having any suitable bandgap. For example, each metal chalcogenide material can include indium sulfide (e.g., In₂S₃), indium oxide (e.g., In₂O₃), indium selenide (e.g., In₂Se₃) or any suitable indium chalcogenide (e.g., In₂(O,S,Se)₃), zinc sulfide (e.g., ZnS), zinc oxide (e.g., ZnO), zinc selenide (e.g., ZnSe) or any suitable zinc chalcogenide (e.g., Zn(O,S,Se)). The bandgap profile of the metal chalcogenide layer stack can have a monotonic bandgap gradient, notched bandgap gradient, or any suitable bandgap profile. For example, the bandgap profile could be notched, in which first metal chalcogenide layer 141 and second metal chalcogenide layer 143 can have similar or same bandgap.

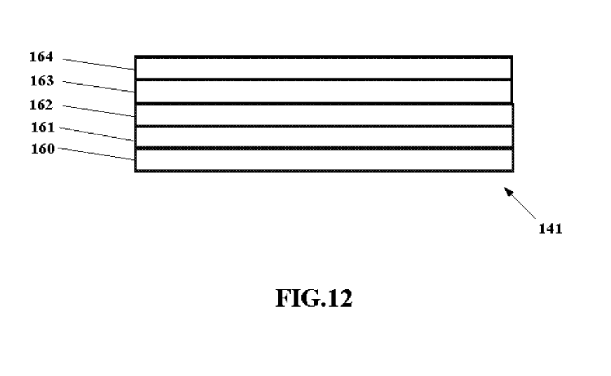

Referring to FIG. 12, an enlarged view of first metal chalcogenide layer 141 is depicted. First metal chalcogenide layer can include one or more metal chalcogenide monolayers, which can include the same metal chalcogenide. For example, first metal chalcogenide layer 141 can include first metal chalcogenide monolayer 160, second metal chalcogenide monolayer 161, third metal chalcogenide monolayer 162, fourth metal chalcogenide monolayer 163, and fifth metal chalcogenide monolayer 164. First metal chalcogenide layer 141 can include any suitable number of metal chalcogenide monolayers to provide the desired characteristics (including thickness) of first metal chalcogenide layer 141. For example, first metal chalcogenide layer 141 can include between 1 and 50 metal chalcogenide monolayers; between 1 and 20 metal chalcogenide monolayers; between 1 and 10 metal chalcogenide monolayers; or between 1 and 5 metal chalcogenide monolayers. The other metal chalcogenide layers 142, 150, 151, 152, 153, 154 can include a similar structure as described in reference to first metal chalcogenide layer 141, and can include different metal chalcogenides from first metal chalcogenide layer 141 and each other.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A method of manufacturing a photovoltaic device, comprising:
forming a semiconductor absorber layer adjacent to a substrate, wherein the semiconductor absorber layer comprises copper, indium, gallium, selenium and/or sulfur; and
forming a buffer layer adjacent to the semiconductor absorber layer, wherein forming the buffer layer comprises forming a first metal chalcogenide layer having a first bandgap adjacent to the semiconductor absorber layer and forming a second metal chalcogenide layer having a second bandgap adjacent to the first metal chalcogenide layer, wherein forming the first metal chalcogenide layer comprises pulsing a first metal precursor and pulsing a first chalcogen precursor and forming the second metal chalcogenide layer comprises pulsing a second metal precursor and pulsing a second chalcogen precursor.

2. The method of claim 1, wherein forming the first metal chalcogenide layer comprises forming one or more first metal chalcogenide monolayers and forming the second metal chalcogenide layer comprises forming one or more second metal chalcogenide monolayers.

3. The method of claim 2, wherein each of the first metal chalcogenide monolayers comprises a same first metal chalcogenide.

4. The method of claim 2, wherein each of the second metal chalcogenide monolayers comprises a same second metal chalcogenide.

5. The method of claim 1, further comprising forming a conducting layer adjacent to the substrate before forming the semiconductor absorber layer adjacent to the substrate.

6. The method of claim 1, further comprising:
forming a transparent conductive oxide layer adjacent to the buffer layer; and
forming a semiconductor window layer adjacent to the buffer layer.

7. The method of claim 1, wherein each of the first and second metal precursors comprises a material selected from the group consisting of indium, zinc, trimethylindium, indium acetylacetonate, indium chloride, dimethylzinc and trimethylzinc.

8. The method of claim 1, wherein each of the first and second chalcogen precursors comprises a material selected from the group consisting of oxygen, sulfur, selenium, water, ozone, sulfur dioxide, hydrogen sulfide, hydrogen selenide, and diethylselenide.

9. The method of claim 1, wherein each of the first and second metal chalcogenide layers comprises a material selected from the group consisting of indium sulfide, indium selenide, indium oxide, zinc sulfide, zinc selenide, and zinc oxide.

10. The method of claim 1, further comprising forming a third metal chalcogenide layer adjacent to the first metal chalcogenide layer before forming the second metal chalcogenide layer, wherein the third metal chalcogenide layer has a bandgap different from the first bandgap and the second bandgap.

11. The method of claim 10, wherein forming the third metal chalcogenide layer comprises pulsing a third metal precursor and pulsing a third chalcogen precursor.

12. The method of claim 10, wherein the third metal chalcogenide layer comprises a material selected from the group consisting of indium sulfide, indium selenide, indium oxide, zinc sulfide, zinc selenide, and zinc oxide.

13. The method of claim 10, further comprising forming a fourth metal chalcogenide layer adjacent to the third metal chalcogenide layer before forming the second metal chalcogenide layer, wherein the fourth metal chalcogenide layer has a bandgap different from the third bandgap and the second bandgap.

14. The method of claim 13, wherein the fourth metal chalcogenide layer comprises a material selected from the group consisting of indium sulfide, indium selenide, indium oxide, zinc sulfide, zinc selenide, and zinc oxide.

15. The method of claim 13, further comprising forming a fifth metal chalcogenide layer adjacent to the fourth metal chalcogenide layer before forming the second metal chalcogenide layer, wherein the fifth metal chalcogenide layer has a bandgap different from the fourth bandgap and the second bandgap.

16. The method of claim 15, wherein the fifth metal chalcogenide layer comprises a material selected from the group consisting of indium sulfide, indium selenide, indium oxide, zinc sulfide, zinc selenide, and zinc oxide.

17. The method of claim 15, further comprising forming a sixth metal chalcogenide layer adjacent to the fifth metal chalcogenide layer before forming the second metal chalcogenide layer, wherein the sixth metal chalcogenide layer has a bandgap different from the fifth bandgap and the second bandgap.

18. The method of claim 17, wherein the sixth metal chalcogenide layer comprises a material selected from the group consisting of indium sulfide, indium selenide, indium oxide, zinc sulfide, zinc selenide, and zinc oxide.

19. The method of claim 17, further comprising forming at least one additional metal chalcogenide layer adjacent to the sixth metal chalcogenide layer before forming the second metal chalcogenide layer, wherein the at least one additional metal chalcogenide layer has a bandgap different from the sixth bandgap and the second bandgap.

20. The method of claim 19, wherein the at least one additional metal chalcogenide layer comprises a material selected from the group consisting of indium sulfide, indium selenide, indium oxide, zinc sulfide, zinc selenide, and zinc oxide.

21. The method of claim 1, further comprising displacing one of the precursors with inert gas after pulsing the precursor.

22. The method of claim 1, further comprising heating the substrate before pulsing a precursor.

23. The method of claim 22, further comprising controlling the temperature based on the metal chalcogenide layer being formed.

24. A structure, comprising
a substrate;
a conducting layer adjacent to the substrate;
a semiconductor absorber layer adjacent to the conducting layer, wherein the semiconductor absorber layer comprises copper, indium, gallium, selenium and/or sulfur; and
a buffer layer adjacent to the semiconductor absorber layer, wherein the buffer layer comprises a first metal chalcogenide layer adjacent to the semiconductor absorber layer and having a first bandgap and a second metal chalcogenide layer adjacent to the first metal chalcogenide layer and having a second bandgap.

25. The structure of claim 24, further comprising:
a semiconductor window layer adjacent to the buffer layer; and
a transparent conductive oxide layer adjacent to the semiconductor window layer.

26. The structure of claim 24, wherein each of the first and second metal chalcogenide layers comprises a material selected from the group consisting of indium sulfide, indium selenide, indium oxide, zinc sulfide, zinc selenide, and zinc oxide.

27. The structure of claim 24, wherein each of the first and second metal chalcogenide layers comprises one or more metal chalcogenide monolayers formed by pulsing a metal precursor and pulsing a chalcogen precursor.

28. The structure of claim 24, further comprising a third metal chalcogenide layer between the first metal chalcogenide layer and the second metal chalcogenide layer, wherein the third metal chalcogenide layer has a bandgap different from the first bandgap and the second bandgap.

29. The structure of claim 28, wherein the third metal chalcogenide layer comprises a material selected from the group consisting of indium sulfide, indium selenide, indium oxide, zinc sulfide, zinc selenide, and zinc oxide.

30. The structure of claim 28, further comprising a fourth metal chalcogenide layer between the third metal chalcogenide layer and the second metal chalcogenide layer, wherein the fourth metal chalcogenide layer has a bandgap different from the third bandgap and the second bandgap.

31. The structure of claim 30, wherein the fourth metal chalcogenide layer comprises a material selected from the group consisting of indium sulfide, indium selenide, indium oxide, zinc sulfide, zinc selenide, and zinc oxide.

32. The structure of claim 30, further comprising a fifth metal chalcogenide layer between the fourth metal chalcogenide layer and the second metal chalcogenide layer, wherein the fifth metal chalcogenide layer has a bandgap different from the fourth bandgap and the second bandgap.

33. The structure of claim 32, wherein the fifth metal chalcogenide layer comprises a material selected from the group consisting of indium sulfide, indium selenide, indium oxide, zinc sulfide, zinc selenide, and zinc oxide.

34. The structure of claim 32, further comprising a sixth metal chalcogenide layer between the fifth metal chalcogenide layer and the second metal chalcogenide layer, wherein the sixth metal chalcogenide layer has a bandgap different from the fifth bandgap and the second bandgap.

35. The structure of claim 34, wherein the sixth metal chalcogenide layer comprises a material selected from the group consisting of indium sulfide, indium selenide, indium oxide, zinc sulfide, zinc selenide, and zinc oxide.

36. The structure of claim 24, wherein the first metal chalcogenide layer comprises indium and the second metal chalcogenide layer comprises zinc.

37. The structure of claim 24, wherein the first metal chalcogenide layer comprises zinc and the second metal chalcogenide layer comprises indium

38. The structure of claim 24, wherein the buffer layer comprises a plurality of metal chalcogenide layers between the first metal chalcogenide layer and the second metal chalcogenide layer.
